(19) United States
(12) Patent Application Publication
(10) Pub. No.: US 2005/0249983 A1
(43) Pub. Date: Nov. 10, 2005

(54) Thickness gradient protective overcoat layers by filtered cathodic arc deposition

(75) Inventors: Michael Joseph Stirniman, Fremont, CA (US); Xiaoding Ma, Fremont, CA (US)

Correspondence Address: MCDERMOTT, WILL & EMERY, 600 13th Street, N.W., Washington, DC, 20005-3096, US

(73) Assignee: SEAGATE TECHNOLOGY LLC

(21) Appl. No.: 10/839,255

(22) Filed: May 6, 2004

(51) Int. Cl. C23C 14/32; B05D 3/14

(52) U.S. Cl. 428/834; 204/192.38; 204/298.41; 428/835

(57) ABSTRACT

A method of depositing a layer of a coating material (e.g., DLC protective overcoats of magnetic and magneto-optical recording media) on a surface of a substrate/workpiece, the layer including relatively thin and relatively thick regions defining a thickness gradient at a boundary therebetween, comprising steps of: (a) providing a filtered cathodic arc deposition (FCAD) process/treatment chamber comprising a FCAD source including means for providing a focused plasma beam containing ions of a coating material and means for scanning the plasma beam over a substrate/workpiece surface; (b) providing the process/treatment chamber with a substrate/workpiece including a surface for deposition thereon; and (c) forming on the surface a layer of coating material including the relatively thin and relatively thick regions defining the thickness gradient at the boundary therebetween by scanning the plasma beam over at least a portion of the surface.

### FIELD OF THE INVENTION

The present invention relates to a method and apparatus for forming a layer of a material having zones or regions of different thickness on a substrate by means of filtered cathodic arc deposition (FCAD), and to annular disk-shaped disk-shaped magnetic and magneto-optical (MO) recording media, having a protective overcoat layer, e.g., of a diamond-like carbon (DLC) material, such as ta-C, wherein the thickness of the overcoat layer varies radially from an inner, landing or contact start/stop (CSS) zone, to an outer, data zone.

### BACKGROUND OF THE INVENTION

Magnetic and magneto-optical (MO) recording media typically require an overcoat for wear and corrosion protection, inasmuch as contact start/stop (CSS) failures in hard disk drives can result in unrecoverable data loss. As a consequence, good tribological performance is one of the most stringent requirements for hard disk drives. Various overcoat materials have been developed for use in the manufacture of hard disk drives, including carbon (C), silicon (Si), and zirconium (Zr)-based materials. Of these, carbon-based overcoats have become widely utilized as a standard protective material in the hard disk industry. Various types of carbon-based overcoats, with and without various dopants, such as hydrogen (H), nitrogen (N), fluorine (F), and NₓH_{y} and various deposition methods, such as ion beam deposition, chemical vapor deposition (CVD), cathode sputtering, etc. have been studied for use as protective overcoat materials.

When used in disk-type media employed in CSS type operation, the overcoat typically protects the magnetic or MO thin-film layer(s) at the inner diameter (ID) landing zone from damage when the data transducer head contacts the disk during a start-stop cycle, whereas, in the outer diameter (OD) data zone of the disk, the overcoat functions to protect the disk from environmental factors, such as oxidation or humidity, that can lead to corrosion and/or degradation of film properties. A similar situation exists with disk-type media having a load-unload (LUL) disk-head-interface adjacent the OD of the disk and a data zone adjacent the ID of the disk.

The tribological performance of disk-type media in CSS or LUL operation is highly dependent upon the thickness of the protective overcoat, e.g., of carbon or carbon-based material. In general, thicker carbon-based overcoats exhibit better tribological performance than thinner overcoats. However, an increase in the thickness of the overcoat results in a concomitant increase in the spacing, or flying height, of the magnetic head or other type data transducer, over the surface of the magnetic medium, which, inter alia, limits the recording density and degrades performance parameters such as, for example, signal-to-medium noise ratio (SMNR).

As is evident from the foregoing, there are competing requirements for the protective overcoat layer. Specifically, on the one hand, it is generally advantageous to make the protective overcoat layer as thin as possible in order to reduce the spacing between the read/write transducer head and the recording layer(s) of the medium thereby to maximize the SMNR. However, on the other hand, the protective overcoat layer provides wear protection of the recording layer(s) from the read/write transducer head, and the mechanical durability of the media is improved by increasing the thickness of the protective overcoat layer.

In view of the above, and since the most tribologically critical portion of the surface area of annular disk-shaped magnetic recording media is the CSS (i.e., head landing) zone adjacent the inner diameter (ID) or the load-unload (LUL) head-disk interface zone adjacent the outer diameter (OD) and the most critical portion for recording performance in either instance is the data zone, which zones have different overcoat layer thickness requirements, multi-zone protective overcoats have been proposed. One such zone design or concept utilizes a relatively thick protective overcoat (e.g., carbon-based) on the CSS or LUL zone to provide more robust tribological performance and a relatively thin carbon-based overcoat on the data zone to ensure a smaller spacing loss (e.g., SMNR loss) between the transducer head and the magnetic media in order to achieve better performance.

FIG. 1 shows, in cross-sectional schematic view, a magnetic recording disk 10 composed of a base or substrate 12 and incorporating a multi-zone protective overcoat 14 as described above. Disk 10 also includes an underlayer 16 formed directly on the substrate and a magnetic thin film layer 18 formed on the under-layer. Disk 10 further comprises an inner diameter CSS (or landing) zone 20, where, as described above, the transducer head contacts the disk surface during a start/stop cycle. An outer diameter, or data zone 22 extends from the outer edge 20a of the landing zone to the outer diameter 24 of substrate 12. According to the multi-zone concept, protective overcoat 14 which extends between the annular inner diameter region 20b of the CSS zone to the outer edge 22a of the data zone, has a greater thickness in the CSS zone 20 than in the data zone 22. Note that the thickness of the overcoat 14 in the CSS zone 20 is greater than the thickness of the overcoat 14 in the data zone 22.

For magnetic media, the substrate 12 may comprise aluminum (Al), textured if desired and plated with a selected alloy, e.g., nickel-phosphorus (NiP), to achieve a requisite surface hardness. Alternatively, substrate 12 may comprise glass, ceramic, or glass-ceramic composite materials, similarly textured if desired. Conventionally-sized substrates for use in typical magnetic hard disk drives have outer diameters 24 of 130 mm (5.25 in.), 95 mm (3.5 in.), and 65 mm (2.5 in.), with corresponding inner diameters 26 of 40 mm (1.57 in.), 25 mm (0.98 in.), and 20 or 25 mm (0.79 or 0.98 in.).

Underlayer 16 is preferably comprised of sputtered chromium (Cr) or a Cr-based alloy, and the magnetic film layer 18 typically comprises a cobalt (Co)-based alloy. The protective overcoat 14 is comprised of a material imparting good tribological, i.e., wear-resistant, and corrosion protective properties to the medium 10 and is typically composed of carbon (C), zirconium oxide (ZrO₂), silicon (Si), silicon carbide (SiC), or silicon oxide (SiO₂).

Referring now to FIG. 2, shown therein, in perspective view, is a magnetic recording disk 30 having an inner CSS (landing) zone 36 and an outer data zone 40. More specifically, FIG. 2 illustrates an annularly-shaped magnetic recording disk 30 of the type having a protective overcoat thereon as shown in FIG. 1. Annularly-shaped disk 30 includes an inner diameter 32 and an outer diameter 34. Adjacent to the inner diameter 32 is an annularly-shaped, inner diameter CSS (landing) zone 36. When the disk 30 is operated in conjunction with a magnetic transducer head (not shown for illustrative simplicity), the CSS zone 36 is the region where the head makes contact with the disk during start-stop cycles or other intermittent occurrences. In FIG. 2, the edge of the CSS zone 36 is indicated by line 38, which is the boundary between the landing zone 36 and a data zone 40, where magnetic information is stored in the magnetic recording layer of the disk.

As best illustrated in FIG. 1, the thickness transition of the protective overcoat 14 between the thinner and thicker data and CSS zones 22 and 20, respectively, is gradual. In practice, however, such gradual transition of protective overcoat thickness is not particularly useful or satisfactory because full advantage cannot be taken of the relatively thick protective overcoat over the CSS zone 20 providing robust tribological performance and the thinner protective overcoat providing better data recording performance within the relatively wide transition region which includes a significant portion of the width of the data zone 22.

The radial thickness gradient of the multi-zone (carbon-based) protective overcoat layer 14 should be as sharp as possible at the boundary between the CSS landing zone 20 and the data zone 22, and the protective overcoat layer preferably is deposited in a single process step. However, current processing schemes for producing protective overcoat layers with sharply defined zones of different thickness incur a disadvantage arising from the fact that they involve sputter and ion beam deposition (IBD) processes utilizing “whole surface” deposition sources. As a consequence, creation of suitable sharply defined radial thickness gradients utilizing sputter and/or IBD sources requires careful design of deposition shields, process gas pressure, and/or electrode voltages. Unfortunately, however, it is virtually impossible even in the best cases to produce sharp thickness gradients in a single process step utilizing such techniques.

An alternative processing scheme for producing protective overcoat layers with sharply defined radial thickness gradients employs two distinct deposition steps, with special shield means provided for selectively depositing the protective overcoat material only in the CSS or LUL zones, as for example, disclosed in U.S. Pat. Nos. 6,468,405 and 6,569,294 B1 (each commonly assigned with the present application). However, while such 2-step method can produce a sharper gradient than is possible with a single step method (hence single process station), disadvantages incurred by the 2-step methodology/technology include increased capital cost and reduced flexibility for the remaining steps of the deposition process. Moreover, and very importantly, use of currently available sputter and/or IBD methodology/technology is effectively limited to single disk, static deposition processing, i.e., wherein a single disk is maintained stationary relative to the deposition source during formation of the protective overcoat layer. There is no possibility of creating protective overcoat layers with radial thickness gradients in a continuously operating, high product throughput “pass-by” sputter or IBD deposition system, wherein the disks are continuously transported past the deposition source.

In view of the foregoing, there exists a need for improved means and methodology for forming single- and dual-sided magnetic and/or magneto-optical (MO) information storage and read-out disks with protective overcoat layers, which means and methodology provide rapid, simple, and reliable formation of multi-zone protective overcoat layers with abrupt (i.e., narrow) transition zones between thinner and thicker portions respectively formed on data and CSS or LUL zones of the disks.

The present invention addresses and solves the problems attendant upon the manufacture of magnetic and MO media with multi-zone protective overcoats having highly delineated thickness variation between data recording and CSS or LUL zones, while maintaining full compatibility with all aspects of conventional automated disk manufacture technology. Further, the means and methodology provided by the present invention enjoy diverse utility in the manufacture of devices requiring thin film coatings having a gradation in thickness and properties dependent thereon, including, inter alia, optical coatings for various applications where the optical properties (e.g., optical density, reflectance, transmittance, absorptance, scattering, etc.) must be varied in a selected (e.g., radial) direction, and coatings for selectively modifying the physical and/or chemical properties of a surface in a selected (e.g., radial) direction for providing a desired property, e.g., anti-friction, corrosion prevention, hardness, roughness, etc.

### DISCLOSURE OF THE INVENTION

An advantage of the present invention is an improved method of depositing a layer of a coating material on a surface of a substrate/workpiece by means of filtered cathodic arc deposition (FCAD), the layer including relatively thin and relatively thick regions defining a thickness gradient at a boundary therebetween.

Another advantage of the present invention is an improved method of depositing a layer of a protective overcoat material on a surface of a magnetic or magneto-optical recording medium by means of FCAD, the layer including relatively thin and relatively thick regions defining a thickness gradient at a boundary between a data zone and a CSS zone or a LUL head-disk interface zone.

Yet another advantage of the present invention is an improved apparatus for depositing a layer of a coating material on a surface of a substrate/workpiece by means of filtered cathodic arc deposition (FCAD), the layer including relatively thin and relatively thick regions defining a thickness gradient at a boundary therebetween.

Still another advantage of the present invention is an improved apparatus for depositing a layer of a protective overcoat material on a surface of a magnetic or magneto-optical recording medium by means of FCAD, the layer including relatively thin and relatively thick regions defining a thickness gradient at a boundary between a data zone and a CSS zone or a LUL head-disk interface zone.

A further advantage of the present invention is improved magnetic or magneto-optical (MO) recording media comprising a DLC protective overcoat layer formed by FCAD and including relatively thin and relatively thick regions defining a thickness gradient at a boundary between a data zone and a CSS zone or a LUL head-disk interface zone.

Additional advantages and other features of the present invention will be set forth in the description which follows and in part will become apparent to those having ordinary skill in the art upon examination of the following or may be learned from the practice of the present invention. The advantages of the present invention may be realized and obtained as particularly pointed out in the appended claims.

According to one aspect of the present invention, the foregoing and other advantages are obtained in part by an improved method of depositing a layer of a coating material on a surface of a substrate/workpiece, the layer including relatively thin and relatively thick regions defining a thickness gradient at a boundary therebetween, comprising steps of:
(a) providing a filtered cathodic arc deposition (FCAD) process/treatment chamber comprising a FCAD source including means for providing a focused plasma beam containing ions of a coating material and means for scanning the plasma beam over a substrate/workpiece surface;
(b) providing the process/treatment chamber with a substrate/workpiece including a surface for deposition thereon; and
(c) forming on the surface the layer of the coating material including the relatively thin and relatively thick regions defining the thickness gradient at the boundary therebetween by scanning the plasma beam over at least a portion of the surface.

According to preferred embodiments of the present invention, step (b) comprises providing as the substrate/workpiece an annular disk-shaped magnetic or magneto-optical (MO) recording medium including an inner diameter (ID) and an outer diameter (OD) defining respective inner and outer peripheries of the medium; and step (c) comprises forming a layer of a protective overcoat material, e.g., a carbon (C)-containing material, such as diamond-like carbon (DLC).

Further preferred embodiments of the invention include those wherein step (c) comprises forming the relatively thick layer of the coating material on a region of the surface adjacent the ID and defining a CSS landing zone of the medium, the relatively thin layer of the coating material defining a data zone of the medium adjacent the OD; and those wherein step (c) comprises forming the relatively thick layer of the coating material on a region of the surface adjacent the OD and defining a load-unload (LUL) head-disk interface zone of the medium, the relatively thin layer of the coating material defining a data zone of the medium adjacent the ID.

According to an embodiment of the present invention, step (b) comprises providing a magnetic or MO recording medium having a uniform thickness first layer of the coating material on the entirety of the surface; and step (c) comprises selectively depositing a second layer of the coating material on a region of the surface adjacent the ID defining the CSS landing zone of the medium or on a portion of the surface adjacent the OD defining the LUL head-disk interface zone of the medium, wherein the first layer and the combination of the first layer and the selectively formed second layer respectively form the relatively thin and relatively thick zones or regions defining the thickness gradient at the boundary therebetween.

In accordance with an alternative embodiment of the invention, step (c) comprises scanning the plasma beam at a slower rate over the region of the surface adjacent the ID defining the CSS landing zone than over the data zone adjacent the OD; or step (c) comprises scanning the plasma beam at a slower rate over the region of the surface adjacent the OD defining the LUL head-disk interface zone than over the data zone adjacent the ID.

According to another alternative embodiment of the present invention, step (c) comprises scanning the plasma beam at a higher deposition rate over the region of the surface adjacent the ID defining the CSS landing zone than over the data zone adjacent the OD; or step (c) comprises scanning the plasma beam at a higher deposition rate over the region of the surface adjacent the OD defining the LUL head-disk interface zone than over the data zone adjacent the ID.

In a further alternative embodiment according to the invention, step (c) comprises scanning a more narrowly focused plasma beam over the region of the surface adjacent the ID defining the CSS landing zone than over the data zone adjacent the OD; or step (c) comprises scanning a more narrowly focused plasma beam over the region of the surface adjacent the OD defining the LUL head-disk interface zone than over the data zone adjacent the ID.

Still other embodiments of the invention include those which further comprise a step of:
(d) continuously moving the medium in a path past the FCAD source during the scanning of the plasma beam in step (c), e.g., moving the medium in a linear or curvilinear path.

According to still further embodiments of the present invention, step (a) further comprises providing the FCAD process/treatment chamber as part of a multi-chamber apparatus; and step (b) comprises providing the FCAD process/treatment chamber with a recording medium transported thereto from an adjacent processing/treatment chamber.

Another aspect of the present invention is an improved apparatus adapted for depositing a layer of a coating material on a surface of a substrate/workpiece, the layer including relatively thin and relatively thick regions defining a thickness gradient at a boundary therebetween, comprising:
(a) a filtered cathodic arc deposition (FCAD) process/treatment chamber comprising a FCAD source, the FCAD source including:
   (i) means for providing a focused plasma beam containing ions of a coating material; and
   (ii) means for scanning the plasma beam over a substrate/workpiece surface; and
(b) means for transporting at least one substrate/workpiece past the scanned plasma beam.

According to embodiments of the present invention, the FCAD source further includes one or more of:
(iii) means for varying the size of the plasma beam;
(iv) means for varying the deposition rate provided by the plasma beam; and
(v) means for varying the scanning rate of the plasma beam.

Further embodiments of the present invention include those wherein the FCAD process/treatment chamber forms part of a multi-chamber continuous manufacturing apparatus comprising at least one other process/treatment chamber operatively connected thereto.

Yet another aspect of the present invention is an improved magnetic or magneto-optical (MO) recording medium, comprising:
(a) a substrate having a surface;
(b) a stack of thin film layers on the substrate surface, the layer stack including at least one magnetic or MO recording layer; and
(c) a protective overcoat layer overlying the layer stack, the protective overcoat layer comprising a diamond-like carbon (DLC) material formed by filtered cathodic arc deposition (FCAD) and including relatively thin and relatively thick regions defining a thickness gradient at a boundary therebetween.

In accordance with preferred embodiments of the present invention, the substrate is annular disk-shaped and includes an inner diameter (ID) and an outer diameter (OD) defining respective inner and outer peripheries of the medium; and the relatively thick layer of the coating material is on a region of the surface adjacent the ID and defines a CSS landing zone of the medium, and the relatively thin layer of the coating material is on a region of the surface adjacent the OD and defines a data zone of the medium; or the relatively thick layer of the coating material is on a region of the surface adjacent the OD and defines a load-unload (LUL) head-disk interface zone of the medium, and the relatively thin layer of the coating material is on a region of the surface adjacent the ID and defines a data zone of the medium.

Additional advantages and features of the present invention will become readily apparent to those skilled in the art from the following detailed description, wherein only preferred embodiments of the invention are shown and described, simply by way of illustration of the best mode contemplated for practicing the present invention. As will be described, the present invention is capable of other and different embodiments, and its several details are susceptible of modification in various obvious respects, all without departing from the spirit of the present invention. Accordingly, the drawings and description are to be regarded as illustrative in nature, and not as limitative.

### BRIEF DESCRIPTION OF THE DRAWINGS

The following detailed description of the embodiments of the present invention can best be understood when read in conjunction with the following drawings, wherein:

FIG. 1 is a cross-sectional schematic view of a magnetic disk having a protective overcoat layer with a thickness gradient;

FIG. 2 is a perspective view of a magnetic disk as in FIG. 1 for illustrating the CSS (landing) and data zones thereof;

FIG. 3 is a simplified, cross-sectional schematic view of a multi-chamber “pass-by” processing/treatment apparatus according to an embodiment of the present invention and including a FCAD process/treatment chamber with a FCAD source; and

FIG. 4 is a graph for illustrating an estimated radial thickness profile of a carbon overcoat layer formed on an annular disk according to an embodiment of the scanned FCAD method of the present invention.

### DESCRIPTION OF THE INVENTION

The present invention is based upon recognition by the inventors that use of filtered cathodic arc deposition (FCAD) technology for forming coating layers with regions of different thickness, e.g., thickness gradient protective overcoat layers on disk-shaped magnetic and magneto-optical (MO) recording media, offers several advantages and capabilities not obtainable according to other methodologies. Specifically:
(1) diamond-like carbon (DLC)-based protective overcoat layers formed by FCAD, e.g., of tetrahedral amorphous carbon (ta-C), are more dense than DLC protective overcoat layers formed by other commonly utilized techniques, e.g., I-C:H formed by ion beam deposition (IBD) and a-C:H formed by sputtering or plasma enhanced chemical vapor deposition (PECVD); and thus afford greater mechanical and corrosion protection of disk-type recording media; and
(2) formation of thickness gradient coatings, e.g., protective overcoat layers having radial thickness gradients with greater thickness at media zones which are subject to head slider contact than at data zones, utilizing the abovementioned commonly utilized deposition techniques (IBD, sputtering, and PECVD), is possible only in single-disk static deposition systems, i.e., systems wherein a disk is maintained stationary relative to the deposition source during the deposition process. However, the increased deposition rates possible with FCAD technology readily facilitate advantageous formation of thickness gradient protective overcoat layers in a “pass-by” manner, i.e., where disks continuously move past a coating material source, thereby resulting in a significant increase in product throughput rate, hence lowered cost for economic competitiveness.

Filtered cathodic arc deposition (FCAD) apparatus create a narrow, focused beam of plasma containing ions of a coating material derived from a cathode source subjected to a high intensity arc discharge, as for example, disclosed in U.S. Pat. Nos. 5,279,723; 6,027,619; 6,236,543 B1; and 6,506,292 B2, the entire disclosures of which are incorporated herein by reference. The focused plasma beam, from which particles exceeding a selected size have been removed by suitable filtering means, can be readily directed to any selected area of a substrate/workpiece via use of a magnetic X-Y scanning coil. The size (e.g., width or diameter) of the plasma beam is typically on the order of 1 cm in diameter; however, increased focusing can provide beams with smaller diameters.

In contrast with other “full surface” deposition processes commonly utilized for forming protective overcoat layers, e.g., IBD, sputtering, and PECVD, the plasma beam provided by a FCAD source can be rapidly scanned in a first step over the entire surface of the substrate/workpiece, e.g., an annular disk-shaped magnetic or MO recording medium including a layer stack with at least one recording layer formed on a surface thereof, to form a uniform thickness layer of a protective overcoat material (e.g., ta-C) thereon. In a second, subsequent step, the plasma beam may be selectively scanned over a CSS landing zone adjacent the ID of the disk or over a LUL head-disk interface zone adjacent the OD of the disk in order to create a desired thickness gradient between the CSS or LUL zones and the data zone. Advantageously, since the scanning speed of the plasma beam is substantially greater than the transport speed of the substrate/workpiece (i.e., disk) past the FCAD source of a “pass-by” deposition system, coating layers (e.g., protective overcoats) with a radial thickness gradient can be readily formed in “pass-by” manner utilizing FCAD technology.

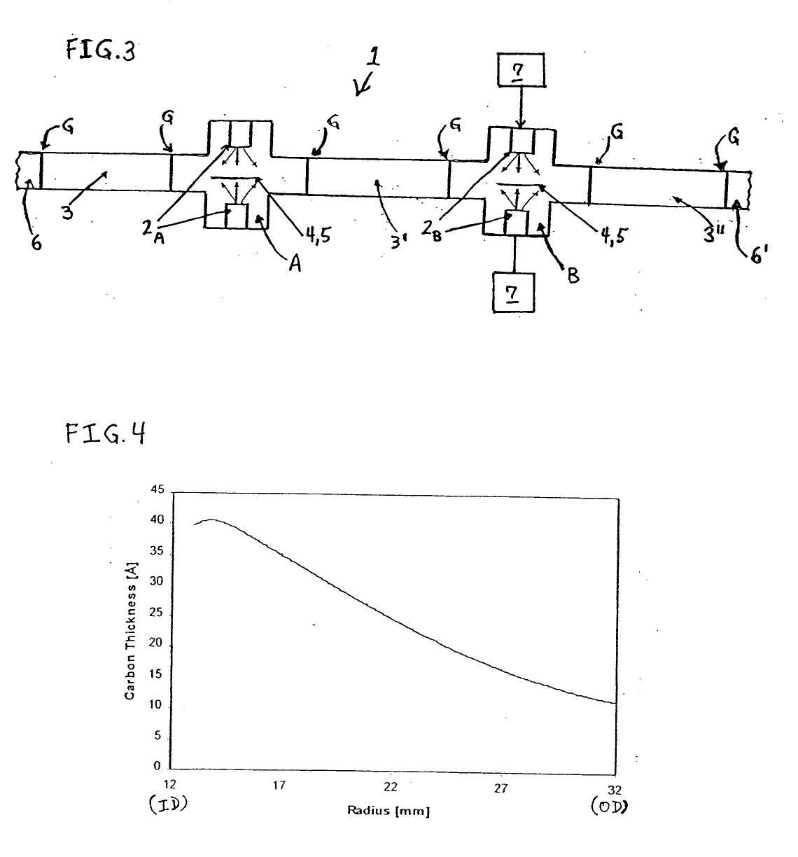

Referring now to FIG. 3, shown therein is a simplified, cross-sectional schematic view of a multi-chamber “pass-by” processing/treatment apparatus 1 according to an embodiment of the present invention and including a FCAD process/treatment chamber with a FCAD source. As illustrated, apparatus 1 comprises a series of linearly elongated vacuum chambers interconnected by a plurality of gate means G of conventional design, the vacuum chambers forming a plurality of processing/treatment chambers or stations, illustratively first and second treatment chambers or stations A and B, respectively including at least one treatment source 2_{A} and 2_{B}. In the illustrated embodiment, first processing/treatment chamber or station A is shown as including a pair of oppositely facing treatment sources 2_{A} for processing/treating (e.g., coating) both surfaces of a substrate/workpiece 4 (e.g., an annular disk substrate of a magnetic or MO recording medium) supported on and transported through the processing/treatment chamber or station by a suitable holder or mounting means 5. Treatment sources 2_{A} may, for example, be selected from among a variety of physical vapor deposition (PVD) sources, such as vacuum evaporation, sputtering, ion plating, etc. sources, and/or from among a variety of plasma treatment sources, such as sputter/ion etching, hydrogen, nitrogen, oxygen, argon, etc. plasma sources) for performing simultaneous treatment of both sides of the dual-sided substrate/workpiece.

According to the illustrated embodiment of the invention, the second processing/treatment chamber or station B includes at least one, illustratively a pair of oppositely facing filtered cathodic arc deposition (FCAD) sources 2_{B} for coating) both surfaces of substrate/workpiece 4 supported on and transported through the processing/treatment chamber or station by holder or mounting means 5. Each FCAD source 2_{B} is of conventional design and includes means for providing a focused plasma beam containing ions of a coating material and control means 7 for scanning the plasma beam over the surface of substrate/workpiece 4. According to embodiments of the invention, control means 7 further includes one or more of: means for varying the size of the plasma beam; means for varying the deposition rate provided by the plasma beam; and means for varying the scanning rate of the plasma beam.

Apparatus 1 further includes a pair of buffer/isolation chambers such as 3, 3′ and 3′, 3″ at opposite lateral ends of respective treatment chambers or stations A and B for insertion and withdrawal, respectively, of workpieces/substrates 4, illustratively annular disk-shaped substrates 4 for magnetic or MO recording media carried by the workpiece/substrate mounting/transport means 5 for “pass-by” transport through apparatus 1. Chambers 6, 6′ respectively connected to the distal ends of inlet and outlet buffer/isolation chambers 3, 3″ are provided for use of apparatus 1 as part of a larger, continuously operating, in-line apparatus wherein workpieces/substrates 4 receive processing/treatment antecedent and/or subsequent to processing in apparatus 1.

Apparatus 1 is provided with conventional vacuum means (not shown in the drawing for illustrative simplicity) for maintaining the interior spaces of each of the treatment chambers A and B and buffer/isolation chambers 3, 3′, 3″, etc. at a reduced pressure below atmospheric pressure, and with means for supplying at least selected ones with an appropriate process gas (not shown in the drawing for illustrative simplicity). Apparatus 1 is further provided with a workpiece/substrate conveyor/transporter means of conventional design (not shown in the drawings for illustrative simplicity) for linearly transporting the workpiece/substrate mounting means 5 through the respective gate means G from chamber-to-chamber in its travel through apparatus 1.

According to embodiments of the present invention, a layer of a coating material including relatively thin and relatively thick regions defining a thickness gradient at a boundary therebetween is deposited on a surface of a substrate/workpiece by means of a method comprising steps of:
(a) providing an apparatus (such as apparatus 1) comprising a filtered cathodic arc deposition (FCAD) process/treatment chamber equipped with a FCAD source including a means for providing a focused plasma beam containing ions of a coating material and a control means for scanning the plasma beam over the substrate/workpiece surface and, depending upon the specific process utilized, for varying the scanning rate, focus, and intensity of the plasma beam;
(b) supplying the process/treatment chamber with a substrate/workpiece including a surface for deposition thereon; and
(c) forming the layer of the coating material including the relatively thin and relatively thick regions defining the thickness gradient at the boundary therebetween by scanning the plasma beam over at least a portion of the surface of the substrate/workpiece.

According to preferred embodiments of the present invention, the substrate/workpiece is an annular disk-shaped magnetic or magneto-optical (MO) recording medium including an inner diameter (ID) and an outer diameter (OD) defining respective inner and outer peripheries of the medium; and a layer of a protective overcoat material, e.g., a DLC material, such as ta-C, is formed on the surface of the medium by FCAD.

Depending upon the nature or type of disk system for which the recording medium is intended to be used in, the relatively thick layer of the coating material (e.g., ta-C) is formed on a region of the surface adjacent the ID and defines a CSS landing zone of the medium, and the relatively thin layer of the coating material defines a data zone of the medium adjacent the OD; or the relatively thick layer of the coating material is formed on a region of the surface adjacent the OD and defines a load-unload (LUL) head-disk interface zone of the medium, and the relatively thin layer of the coating material defines a data zone of the medium adjacent the ID.

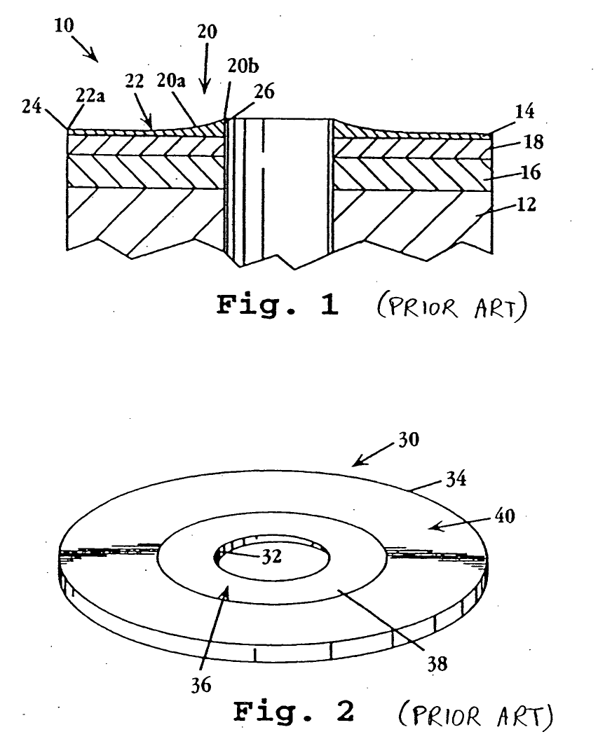

According to an embodiment of the present invention, the substrate/workpiece in the form of a magnetic or MO recording medium is provided with a uniform thickness first layer of the DLC coating material on the entirety of the surface, as by a first deposition step performed in the FCAD chamber or in a different, e.g., adjacent, chamber of a multi-chamber apparatus such as illustrated in FIG. 1. A second layer of the DLC coating material is then selectively deposited in a second deposition step performed in the FCAD chamber, i.e., selectively deposited on a region of the surface adjacent the ID defining the CSS landing zone of the medium or on a portion of the surface adjacent the OD defining the LUL head-disk interface zone of the medium by scanning of the FCAD plasma beam over the selected regions. The first layer and the combination of the first layer and the selectively formed second layer respectively form the relatively thin and relatively thick zones or regions defining the thickness gradient at the boundary therebetween.

In an alternative embodiment, the thinner and thicker portions of the layer of coating material are both formed in the FCAD chamber by scanning the plasma beam at a slower rate over the region of the surface adjacent the ID defining the CSS landing zone than over the data zone adjacent the OD, or by scanning the plasma beam at a slower rate over the region of the surface adjacent the OD defining the LUL head-disk interface zone than over the data zone adjacent the ID.

According to another alternative embodiment, the thinner and thicker portions of the layer of coating material are both formed in the FCAD chamber by scanning the plasma beam at a higher deposition rate over the region of the surface adjacent the ID defining the CSS landing zone than over the data zone adjacent the OD, or by scanning the plasma beam at a higher deposition rate over the region of the surface adjacent the OD defining the LUL head-disk interface zone than over the data zone adjacent the ID.

In a still further alternative embodiment, the thinner and thicker portions of the layer of coating material are both formed in the FCAD chamber by scanning a more narrowly focused plasma beam over the region of the surface adjacent the ID defining the CSS landing zone than over the data zone adjacent the OD, or by scanning a more narrowly focused plasma beam over the region of the surface adjacent the OD defining the LUL head-disk interface zone than over the data zone adjacent the ID.

In each of the above-described embodiments, the substrate/workpiece (e.g., magnetic or MO recording medium) may be continuously moved in a path past the FCAD source during exposure to the plasma beam, e.g., moving in a linear or curvilinear path, in view of the high deposition and beam scanning rates possible with FCAD technology.

### EXAMPLE

A FCAD plasma beam containing carbon particles was scanned around the ID of an annular disk-shaped recording medium with a 12 mm radius at the ID and a 32 mm radius at the OD to form a FCAD carbon layer with a thickness gradient between the ID and the OD. FIG. 4 is a graph illustrating an estimated radial thickness profile of the carbon layer formed by the scanned FCAD method of the present invention, which radial thickness profile was obtained by assuming a linear relationship between the reflectivity of the FCAD carbon layer and its thickness, and by estimating the thickness at the ID and OD to be ˜40 Å and ˜10 Å, respectively. While this medium was fabricated with a relatively large width (i.e., ˜1 cm diameter) FCAD plasma beam that had been previously been optimized for providing carbon-containing protective overcoat layers with full surface thickness uniformity and deposition rate, the beam can be focused to a smaller diameter in order to provide a sharper thickness gradient with a narrower transition zone between thinner and thicker layer portions. In addition to the above, the FCAD carbon-containing plasma beam may be scanned around the OD of the disk to provide a thicker protective overcoat layer thereat as a LUD head-disk interface zone.

Thus, the present invention advantageously provides an apparatus and method for forming coatings or layers on selected portions of a substrate surface. The invention enjoys particular utility in the manufacture of disk-shaped magnetic or MO data or information storage/read-out medium requiring deposition of a thicker protective overcoat in a CSS zone or a LUL zone for optimum tribological performance and a thinner protective overcoat in a data zone for optimum parametric performance. In addition, the inventive apparatus and methodology are fully compatible with the requirements of automated, high-throughput magnetic or MO disk manufacture.

In addition to the above-described utility in the manufacture of disk-shaped recording/information retrieval media requiring selective deposition of annularly-shaped areas, the invention is applicable to selective deposition on a wide variety of area shapes and configurations by use of appropriately shaped FCAD plasma beam scanning patterns. Further, the type of coatings deposited by the inventive apparatus and methodology is not limited to the specifically disclosed protective overcoats for recording media. Rather, the invention is broadly applicable to the deposition of various types of optical coatings as may be required in particular applications, wherein optical properties such as optical density, spectral or integral reflectance, spectral or integral transmittance, absorptance, scattering, etc., must be varied in e.g., a radial direction. The invention is also applicable to the formation of coatings which modify the physical and/or chemical properties of a substrate surface in a particular direction, such as for providing a desired anti-friction, corrosion prevention, hardness, roughness, etc., characteristic to a particular surface portion.

In the previous description, numerous specific details are set forth, such as specific materials, structures, reactants, processes, etc., in order to provide a better understanding of the present invention, however, the present invention can be practiced without resorting to the details specifically set forth. In other instances, well-known processing materials and techniques have not been described in detail in order not to unnecessarily obscure the present invention.

Only the preferred embodiments of the present invention and but a few examples of its versatility are shown and described in the present disclosure. It is to be understood that the present invention is capable of use in various other combinations and environments and is susceptible of changes and/or modifications within the scope of the inventive concept as expressed herein.

1. A method of depositing a layer of a coating material on a surface of a substrate/workpiece, said layer including relatively thin and relatively thick regions defining a thickness gradient at a boundary therebetween, comprising steps of:
(a) providing a filtered cathodic arc deposition (FCAD) process/treatment chamber comprising a FCAD source including means for providing a focused plasma beam containing ions of a said coating material and means for scanning said plasma beam over a substrate/workpiece surface;
(b) providing said process/treatment chamber with a substrate/workpiece including a surface for deposition thereon; and
(c) forming on said surface said layer of said coating material including said relatively thin and relatively thick regions defining said thickness gradient at said boundary therebetween by scanning said plasma beam over at least a portion of said surface.

2. The method as in claim 1, wherein:
step (b) comprises providing as said substrate/workpiece an annular disk-shaped magnetic or magneto-optical (MO) recording medium including an inner diameter (ID) and an outer diameter (OD) defining respective inner and outer peripheries of said medium.

3. The method as in claim 2, wherein:
step (c) comprises forming a layer of a protective overcoat material.

4. The method as in claim 3, wherein:
step (c) comprises forming a layer of a carbon (C)-containing material.

5. The method as in claim 2, wherein:
step (c) comprises forming said relatively thick layer of said coating material on a region of said surface adjacent said ID and defining a CSS landing zone of said medium, said relatively thin layer of said coating material defining a data zone of said medium adjacent said OD; or
step (c) comprises forming said relatively thick layer of said coating material on a region of said surface adjacent said OD and defining a load-unload (LUL) head-disk interface zone of said medium, said relatively thin layer of said coating material defining a data zone of said medium adjacent said ID.

6. The method as in claim 5, wherein:
step (b) comprises providing a magnetic or MO recording medium having a uniform thickness first layer of said coating material on the entirety of said surface; and
step (c) comprises selectively depositing a second layer of said coating material on a region of said surface adjacent said ID defining said CSS landing zone of said medium or on a portion of said surface adjacent said OD defining said LUL head-disk interface zone of said medium, wherein said first layer and the combination of said first layer and said selectively formed second layer respectively form said relatively thin and relatively thick zones or regions defining said thickness gradient at said boundary therebetween.

7. The method as in claim 5, wherein:
step (c) comprises scanning said plasma beam at a slower rate over said region of said surface adjacent said ID defining said CSS landing zone than over said data zone adjacent said OD; or
step (c) comprises scanning said plasma beam at a slower rate over said region of said surface adjacent said OD defining said LUL head-disk interface zone than over said data zone adjacent said ID.

8. The method as in claim 5, wherein:
step (c) comprises scanning said plasma beam at a higher deposition rate over said region of said surface adjacent said ID defining said CSS landing zone than over said data zone adjacent said OD; or
step (c) comprises scanning said plasma beam at a higher deposition rate over said region of said surface adjacent said OD defining said LUL head-disk interface zone than over said data zone adjacent said ID.

9. The method as in claim 5, wherein:
step (c) comprises scanning a more narrowly focused plasma beam over said region of said surface adjacent said ID defining said CSS landing zone than over said data zone adjacent said OD; or
step (c) comprises scanning a more narrowly focused plasma beam over said region of said surface adjacent said OD defining said LUL head-disk interface zone than over said data zone adjacent said ID.

10. The method as in claim 2, further comprising a step of:
(d) continuously moving said medium in a path past said FCAD source during said scanning of said plasma beam in step (c).

11. The method as in claim 10, wherein:
step (d) comprises moving said medium in a linear or curvilinear path.

12. The method as in claim 2, wherein:
step (a) further comprises providing said FCAD process/treatment chamber as part of a multi-chamber apparatus; and
step (b) comprises providing said FCAD process/treatment chamber with a said recording medium transported thereto from an adjacent processing/treatment chamber.

13. An apparatus adapted for depositing a layer of a coating material on a surface of a substrate/workpiece, said layer including relatively thin and relatively thick regions defining a thickness gradient at a boundary therebetween, comprising:
(a) a filtered cathodic arc deposition (FCAD) process/treatment chamber comprising a FCAD source, said FCAD source including:
(i) means for providing a focused plasma beam containing ions of a coating material; and
(ii) means for scanning said plasma beam over a substrate/workpiece surface; and
(b) means for transporting at least one substrate/workpiece past said scanned plasma beam.

14. The apparatus according to claim 13, wherein said FCAD source further includes one or more of:
(iii) means for varying the size of said plasma beam;
(iv) means for varying the deposition rate provided by said plasma beam; and
(v) means for varying the scanning rate of said plasma beam.

15. The apparatus according to claim 13, wherein:
said FCAD process/treatment chamber forms part of a multi-chamber continuous manufacturing apparatus comprising at least one other process/treatment chamber operatively connected thereto.

16. A magnetic or magneto-optical (MO) recording medium, comprising:
(a) a substrate having a surface;
(b) a stack of thin film layers on said substrate surface, said layer stack including at least one magnetic or MO recording layer; and
(c) a protective overcoat layer overlying said layer stack, said protective overcoat layer comprising a diamond-like carbon (DLC) material formed by filtered cathodic arc deposition (FCAD) and including relatively thin and relatively thick regions defining a thickness gradient at a boundary therebetween.

17. The medium according to claim 16, wherein:
said substrate is annular disk-shaped and includes an inner diameter (ID) and an outer diameter (OD) defining respective inner and outer peripheries of said medium.

18. The medium according to claim 17, wherein:
said relatively thick layer of said coating material is on a region of said surface adjacent said ID and defines a CSS landing zone of said medium, and said relatively thin layer of said coating material is on a region of said surface adjacent said OD and defines a data zone of said medium.

19. The medium according to claim 17, wherein:
said relatively thick layer of said coating material is on a region of said surface adjacent said OD and defines a load-unload (LUL) head-disk interface zone of said medium, and said relatively thin layer of said coating material is on a region of said surface adjacent said ID and defines a data zone of said medium.
